(19) United States
(12) Patent Application Publication
(10) Pub. No.: US 2026/0134184 A1
(43) Pub. Date: May 14, 2026

(54) SWITCHING MODELING SYSTEMS AND RELATED METHODS FOR POWER SEMICONDUCTOR DEVICES

(71) Applicant: SEMICONDUCTOR COMPONENTS INDUSTRIES, LLC, Scottsdale, AZ (US)

(72) Inventors: Didier BALOCCO, Beaucroissant (FR); Yunpeng XIAO, Shanghai (CN); James Joseph VICTORY, Trabuco Canyon, CA (US)

(73) Assignee: SEMICONDUCTOR COMPONENTS INDUSTRIES, LLC, Scottsdale, AZ (US)

(21) Appl. No.: 19/116,213

(22) PCT Filed: Mar. 17, 2023
(86) PCT No.: PCT/CN2023/082344

§ 371 Date: Mar. 27, 2025

(51) Int. Cl. G06F 30/367

(52) U.S. Cl. CPC G06F 30/367

(57) ABSTRACT

Implementations of a product system model file generating system may include one or more hardware processors and a first interface generated by a computing device to receive from a user a selection of a product SPICE model for a product including at least one switch; using a second interface to receive from a user a selection of at least a partial soft switching process condition; using a third interface to receive from a user a selection of one or more system characteristics and one or more operating characteristics; using a fourth interface to receive from the user a selection of one or more circuit parameters including a simulation circuit including at least two switches; using a SPICE model simulation module to generate a SPICE model output; and using a formatting module to format the SPICE model output into a product system model file.

### CROSS REFERENCE TO RELATED APPLICATIONS

This application is a 371 National Stage Application claiming priority to the earlier International Application to Balocco entitled “Switching Modeling Systems and Related Methods for Power Semiconductor Devices,” International Application No. PCT/CN 2023/082344, filed Mar. 17, 2023, now pending, the disclosure of which is hereby incorporated entirely herein by reference.

### BACKGROUND

### 1. Technical Field

Aspects of this document relate generally to electronic system simulation. More specific implementations involve systems and methods for simulating systems that include semiconductor die.

### 2. Background

Semiconductor die are incorporated into larger electronic systems like motherboards or circuit boards through being directly attached or attached through a packaging system attached to the semiconductor die. The motherboards or circuit boards are designed to supply/receive certain electronic signals from the semiconductor die during operation.

### SUMMARY

Implementations of a method of generating a product system model file may include using a processor and a first interface generated by a computing device, selecting a product SPICE model for a product including at least one switch; and using a processor and a second interface generated by the computing device, selecting at least a partial soft switching process condition. The method may also include, using a third interface generated by the computing device, receiving from the user one or more system characteristics and one or more operating characteristics; and using a fourth interface generated by the computing device, receiving from the user one or more circuit parameters, the one or more circuit parameters including a simulation circuit including at least one switch. The method may also include, using the processor and a SPICE model simulation module, generating a SPICE model output with the product SPICE model, the at least partial soft switching process condition, the one or more system characteristics, the one or more operating characteristics, and the one or more circuit parameters; and using the processor and a formatting module, formatting the SPICE model output into a product system model file.

Implementations of methods of generating a product system model file may include one, all, or any of the following:

The product system model file may be configured to be used to perform a system level simulation of a system including the product.

The simulation circuit further may include a resonant inductor coupled with the at least one switch.

The simulation circuit further may include a shunt resistor coupled with the at least one switch.

The one or more circuit parameters may further include one of gate resistance, gate inductance, gate loop inductance, source inductance, loop inductance, diode voltage, and any combination thereof.

The one or more circuit parameters may further include one of shunt resistance, printed circuit board leakage inductances, decoupling capacitor series resistance, one or more parasitics in a switching loop, and any combination thereof.

The one or more system characteristics may include an output capacitance of an output capacitor of the at least one switch.

The one or more operating characteristics may include bus voltage.

The one or more system characteristics may include an inductance value of the resonant inductor.

The one or more operating characteristics may include a maximum transition time of switching of the at least one switch.

Generating the SPICE model output further may include using a current in the resonant inductor before a switching event of the at least one switch and using a rate of change of current in the resonant inductor before the switching event of the at least one switch.

Implementations of a product system model file generating system may include one or more hardware processors configured by machine-readable instructions to use a first interface generated by a computing device to receive from a user a selection of a product SPICE model for a product including at least one switch; and use a second interface generated by the computing device to receive from a user a selection of at least a partial soft switching process condition. The system may also include using a third interface generated by the computing device to receive from a user a selection of one or more system characteristics and one or more operating characteristics; and using a fourth interface generated by the computing device to receive from the user a selection of one or more circuit parameters, the one or more circuit parameters including a simulation circuit including at least two switches. The system may also include using a SPICE model simulation module to generate a SPICE model output with the product SPICE model, the at least partial soft switching process condition, the one or more system characteristics, the one or more operating characteristics, and the one or more circuit parameters; and using a formatting module to format the SPICE model output into a product system model file.

Implementations of a product system model file generating system may include one, all, or any of the following:
The product system model file may be configured to be used to perform a system level simulation of a system including the product.

The simulation circuit further may include a resonant inductor coupled with the at least one switch.

The simulation circuit further may include a shunt resistor coupled with the at least one switch.

The one or more circuit parameters may further include one of shunt resistance, printed circuit board leakage inductances, decoupling capacitor series resistance, one or more parasitics in a switching loop, and any combination thereof.

The one or more system characteristics may include an output capacitance of an output capacitor of the at least one switch.

The one or more system characteristics may include an inductance value of the resonant inductor.

The one or more operating characteristics may include a maximum transition time of switching of the at least one switch and a bus voltage.

Using the SPICE model simulation module to generate a SPICE model output with the product SPICE model further may include using a current in the resonant inductor before a switching event of the at least one switch and using a rate of change of current in the resonant inductor before the switching event of the at least one switch.

Implementations of a method of generating a product system model file may include using one or more processors and one or more interfaces generated by a computing device associated with a user. The method may include selecting a product SPICE model for a product comprising at least one switch; selecting a partial soft switching process condition; and receiving one or more system characteristics and one or more operating characteristics. The method may include receiving one or more circuit parameters, the one or more circuit parameters comprising a simulation circuit comprising at least one switch and using a SPICE model simulation module to generate a SPICE model output with the product SPICE model, the partial soft switching process condition, the one or more system characteristics, the one or more operating characteristics, and the one or more circuit parameters. The method may include using a formatting module to format the SPICE model output into a product system model file.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a schematic of an RLC equivalent circuit for a circuit containing at least two semiconductor switches;

FIG. 2 are graphs of current through a resonant inductor and a graph showing the rate of change of voltage VSwt at the location indicated in FIG. 1;

FIG. 3 is a schematic and timing diagram of an implementation of a half bridge circuit operating in boost mode during a double pulse test hard switching operation;

FIG. 4 is a schematic and timing diagram of the implementation of the half bridge circuit operating in buck mode during a double pulse test hard switching operation;

FIG. 5 is a schematic and timing diagram of an implementation of a half bridge circuit operating in boost mode during soft switching operation;

FIG. 6 is a schematic and timing diagram of the implementation of the half bridge circuit operating in buck mode during soft switching operation;

FIG. 7 is a diagram of four quadrants of operation of the half bridge circuits of FIGS. 3-6 during hard and soft switching operations;

FIG. 8 is a schematic of a simulation circuit for two semiconductor switches;

FIG. 9 is a block diagram of an implementation of a switching modeling system; and FIG. 10 is a flow chart of an implementation of a method of generating a product system model file.

### DESCRIPTION

This disclosure, its aspects and implementations, are not limited to the specific components, assembly procedures or method elements disclosed herein. Many additional components, assembly procedures and/or method elements known in the art consistent with the intended switching modeling systems and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such switching modeling systems and implementing components and methods, consistent with the intended operation and methods.

Various implementations of systems and methods for creating product system model files are disclosed in the U.S. Patent Application to Xiao, et al, entitled “Automated Power Discrete and Module Model Generation for System Level Simulators,” Ser. No. 18/058,382, filed Nov. 23, 2022 the disclosure of which is incorporated entirely herein by reference ('382 Application). The product system model files are then used by various system level simulators used by circuit designers during circuit design. The product SPICE models for the semiconductor products disclosed herein, like those disclosed in the '382 Application, are derived through modeling carried out using either or both of the modeling processes disclosed in U.S. Pat. No. 11,481,532 to Victory et al., “Systems and Methods for Designing a Discrete Device Product,” issued Oct. 25, 2022 ('522 Patent), and U.S. Pat. No. 11,481,533 to Victory et al., “Systems and Methods for Designing a Module Semiconductor Product,” issued Oct. 25, 2022 ('533 Patent), the disclosures of each of which are incorporated entirely herein by reference. The term “product SPICE model” as used herein thus means the same as the corresponding “product SPICE model” as used in each of the '532 and '533 Patents. These product SPICE models are the result of significant simulations that take into account the electrical/thermal characteristics of one or more semiconductor die and the electrical/thermal characteristics of the corresponding packaging to which the one or more semiconductor die are coupled and which are used to provide electrical/thermal connections to a circuit or motherboard to which the semiconductor product is coupled. The various system and method implementations disclosed herein utilize product SPICE models like those disclosed in the '532 and '533 Patents to create product system model files that can be used by various system level simulators used by circuit designers during circuit design. These product system model files may take the format of a structured text file, a plain text file, or a delimited text file in various implementations. In some implementations, the product system model file may be a structured text file in an xml format that is structured for use in a Piecewise Linear Electrical Circuit Simulation (PLECS) system level simulator (a PLECS model) marketed by Plexim of Zurich, Switzerland. In other implementations, the product system file may be a structured text, plain text or a delimited text file capable of being utilized in another system level simulator type like the one marketed under the tradename PSIM by Powersim, Inc. of Rockville, MD, or any other system level simulator.

In the case of semiconductor packages and modules that include switching semiconductor devices (switches), various system simulators like those disclosed herein and in the '382 Application utilize hard switching double pulse tests to model the energy loss and behavior. In hard switching, the energy stored in a switch's output capacitor is lost in the switch primarily during the turn-on period of the test, so that at the turn-off portion of the test, the output capacitor must be refilled to allow the switch transition to occur. However, under certain operating conditions, a semiconductor switch can operate using soft switching/in a soft switching operation. In soft switching, part of or the full energy stored in the switch's output capacitor is recycled back to the output capacitor with the assistance of a resonant tank created by an inductor coupled with the switch. The ability to recycle part or all of the energy in the switch's output capacitor helps reduce switching power losses and can increase the overall power efficiency of the switching semiconductor package/system.

Double pulse testing works well to develop product system model files for semiconductor packages that contain semiconductor switches operated in a hard switching mode/operation. However, double pulse testing does not work to accurately predict/measure the lower losses experienced by a semiconductor switch operated using soft switching/in a soft switching mode. This is in part because soft switching modes operate in a continuum from some soft switching to all soft switching. Also, the double pulse testing ignores the effects of the circuits that create the resonant tank. This can lead to large errors in simulations performed using the resulting product system model files by a system level simulator during circuit design. The ability to accurately develop product system model files that comprehend the operation of a given semiconductor package that contains switches may be particularly important for circuit designs where operation does or can operate in at least a partial soft switching mode. Non-limiting examples of such applications and circuit designs where at least partial soft switching can occur include resonant half bridge converters, DC-DC LLC designs, CLLC resonant designs, dual active bridge designs and phase shifted full bridge designs.

Soft switching or partial zero volt transition (ZVT) or partial zero volt switching (ZVS) occurs when the transition occurs while the resonant inductor and the output capacitor of the semiconductor switch resonate to make the voltage swing from one rail to the other rail during a delay between a turn-off event and a turn-on event. During the delay of the transition, both switches (in the case of a half-bridge device) are off during this transition. At the end of the transition, electrical conduction starts with the body diode of the switch and Eon is negative. Also, the voltage reaches the other rail on time or during the period of delay resulting in a partial transition with switching losses where Eon is positive but less than Eon in a hard switching system. In order to initiate a soft switching transition, the resonant inductor current in an inductor electrically coupled with the semiconductor switch is moving an opposition direction from energy transfer or the turn-off body-diode forward current. The total amount of energy in the resonant tank formed by the inductor is important in determining whether a soft switching transition can occur. This total energy in the resonant tank is proportion to, by non-limiting example, the current in the inductor (resonant inductor), the rate of change of current in the resonant inductor, the voltage store in the output capacitor of the semiconductor switch, the bus voltage, and a load reflected voltage by an isolation transformer. The energy in the resonant tank is can also depend on, by non-limiting example, the structure of the inductor-capacitor-resistor network in the particular semiconductor switch/semiconductor package, and a delay between the timing of when each of two switches change state. For example, the amount of delay between when the high side switch turns off and a low side switch turns on can influence whether the two switches operate partially or completely in soft switching mode.

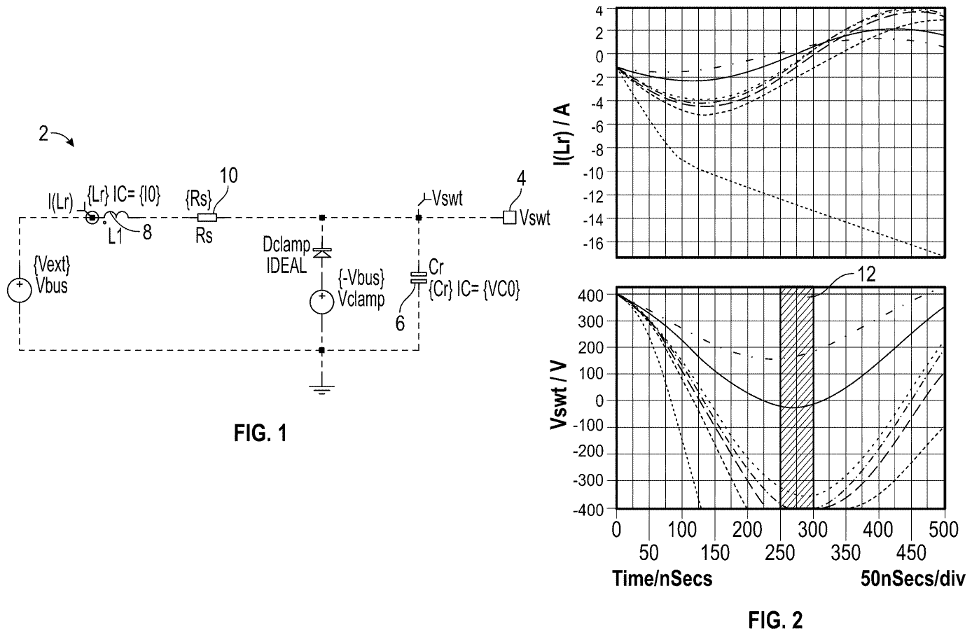

Referring to FIG. 1, an equivalent circuit 2 for a semiconductor package that includes a semiconductor switch for use in a simulation is illustrated. Here, the voltage being monitored during a switching transition is the VSwt point 4 adjacent to the capacitor Cr 6. FIG. 2 illustrates graphs of current through the resonant inductor Lr 8 adjacent to shunt resistor Rs 10 and the rate of change of voltage VSwt for a set of delay values between when a switch turns off and the other turns on (the X axis of the voltage graph). The shaded region 12 in the voltage graph shows a region of maximum likelihood where, at lower energies in the resonant tank formed by the resonant inductor Lr 8, partial soft switching of the semiconductor package is observed. The shade region 12 corresponds to delay values about 250 to 300 nanoseconds (ns). The simulation illustrated in FIG. 2 was conducted where the bus voltage VBus was set to 400 V, 10 is −1 A, the shunt resistor (Rs) was 1 mega Ohm, the inductance of Lr is 10 micro Henries, and the capacitance of Cr was 1 nano Farad. The simulation was carried out as the di/dt variable was varied by stepping dt from 10 ns, 20 ns, 23 ns, 25 ns, 27 ns, 50 ns, and 100 n and plotting the resulting current and voltage values in FIG. 2. The graphs show the effect of the rate of change of the current in the resonant inductor Lr 8. FIGS. 1 and 2 illustrate that for a given semiconductor switching system, the system can operate at least partially in a soft switching mode under particular operating conditions.

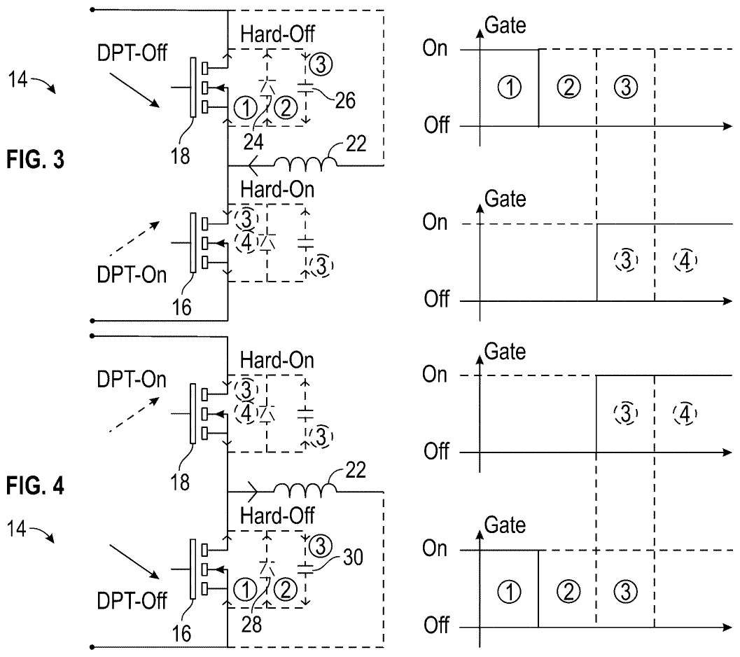

The behavior of a half-bridge circuit with two semiconductor switches during hard and soft switching operation during double pulse testing are illustrated in FIGS. 3-6. In FIG. 3, half bridge circuit 14 with low side switch 16 and high side switch 18 are shown coupled with inductor 22. Here, during a double pulse test, driving of the switches 16, 18 is occurring by the low side as in boost mode. At the turn off of the high side switch 18, the current continues to flow in the body diode represented by diode 24 allowing the output capacitor of the high side switch 18 represented by capacitor 26 to discharge into the low side switch through the inductor 22, resulting in a loss of the charge. In a similar way, referring to FIG. 4, when the half-bridge circuit 14 is driven by the high side switch 18 as in buck mode, when the low side switch 16 turns off, the current continues to flow in the body diode of the low side switch, represented by diode 28. This similarly allows the charge in the output capacitor of the low side switch 16 represented by capacitor 30 to flow and be lost to the high side switch 18. Thus, the double pulse testing of the half bridge circuit relies on/assumes that the charge of the output capacitors of the low side switch 16 and high side switch 18 are entirely lost as the inductor 22 does not store any of the energy in the capacitors.

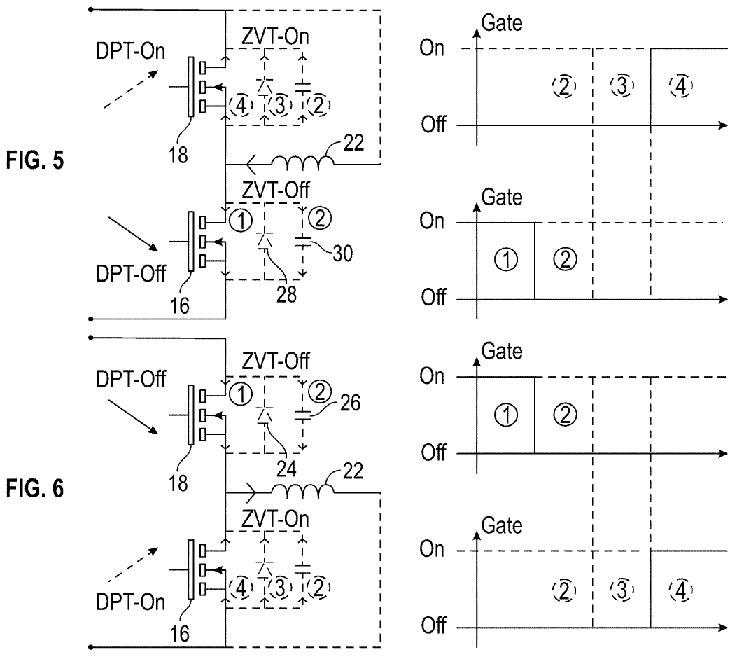

A different operating condition exists in a soft switching operating condition, however, where, referring to FIG. 5, the half bridge circuit 14 is illustrated during boost mode at low side turn-off. Here, as illustrated, because of the energy stored in inductor 22, current cannot flow through the body diode represented by diode 28, which prevents discharge of the charge in the output capacitor of the low side switch 16 represented by capacitor 30. This means that during buck mode, at least some of the original charge of the output capacitor of the low side switch 16 is still present in the output capacitor when the low side switch is switched on. A similar behavior is observed in soft switching operating during the buck mode operation as illustrated in FIG. 6 where at the turn off of the high side switch 18, the energy stored in inductor 22 again prevents current flow in the body diode represented by diode 24. This prevents at least some of the charge in the output capacitor of the high side switch 28 represented by capacitor 26 from discharging, keeping the charge present for recycling when the high side switch 18 is again turned on. Because the energy is stored transiently in the inductor 22, at the proper energies and delay timings, this soft switching behavior is present at proper values of energy and rate of change of current.

In soft switching, the energy depends on the current and also on the rate of change of current (di/dt) to complete a soft transition. In the case of double pulse testing, the di/dt is always increasing, but in soft switching the di/dt can be decreasing which reduces the amount of resonant energy available for the transition. In soft switching, keeping the current in the opposite direction compared to the turn-off switch (high side or low side) body-diode forward for all transitions is the goal. This allows the recycling of the charge in the output capacitors of the switches. Because reaching and measuring soft switching behavior of a given circuit involves varying the rate of change of current (di/dt), a more complex testing set up is needed than that used for a double pulse (buck or boost) test set up. This is because the double pulse test is actually a specific switching case where di/dt=0. Achieving a partial ZVT depends on the resonant energy (energy in the resonant tank) that involves current, di/dt, and voltage bus values along with the maximum delay between high and low side switching events.

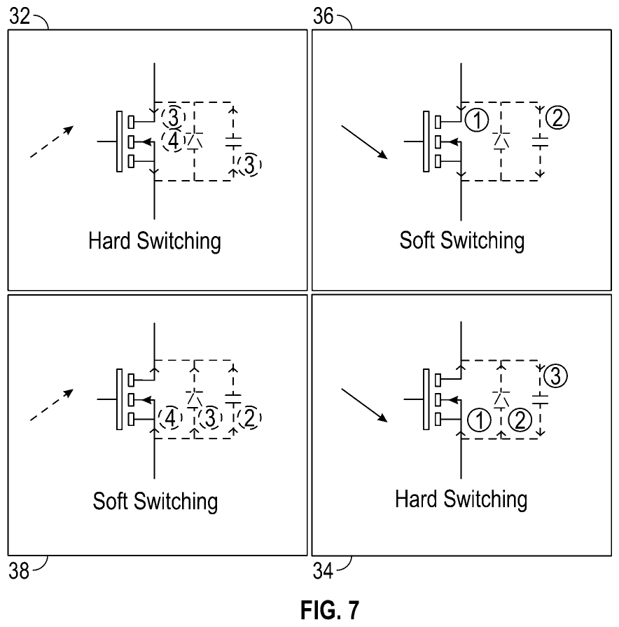

The foregoing process can be summarized using the chart in FIG. 7 which shows four quadrants of operation of each of the switches in the half bridge circuit 14 of FIGS. 3-6. Hard switching operation is illustrated in the top left quadrant 32 and lower right quadrant 34 during turn on and turn off operation respectively. In the top left quadrant 32 the current from the output capacitor is illustrated flowing from the drain to source and in the lower right quadrant 34 the current is illustrated to be flowing from the source to the drain from the output capacitor. Soft switching operation is illustrated in the top right quadrant 36 and lower left quadrant 38. In the top right quadrant 36 the current would be flowing from the drain to the source but is prevented by the body diode. In the lower left quadrant 38 the current would be flowing from the source to the drain but again is prevented from doing so by the body diode. FIG. 7 illustrates how the use of only hard switching with double pulse testing winds up allowing the tester to characterize only half of the possible operating states of a given circuit that includes semiconductor switches.

While the foregoing principles have been discussed in the context of a half bridge circuit that involves two switches, the principles disclosed herein could also be applied to a process of testing a semiconductor package that includes just one semiconductor switch therein. Those of ordinary skill in the art will appreciate how this can be done with the use of an inductor coupled with the single switch to achieve a soft switching condition under the proper operating conditions.

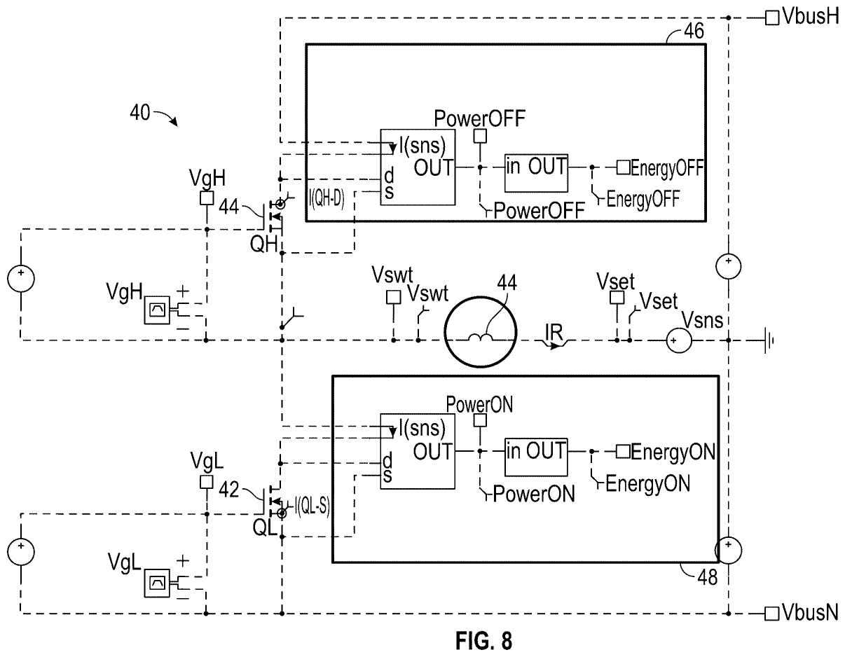

Referring to FIG. 8, an implementation of a test set up 40 for a half bridge circuit is illustrated that shows low side switch 42 and high side switch 44 coupled with inductor 44. During operation of the testing simulation, the components in the first measurement module 46 and in the second measurement module 48 are used to measure those circuit components needed to calculate Eon and Eoff as the various operating and system parameters of the half bridge circuit are varied including, by non-limiting example, bus voltage, current in the resonant inductor 44 before a switching event; the di/dt in the resonant inductor 44 before a switching event; the output capacitor capacitance for each switch 42, 44; the transition/delay time between switching events, and any parasitics in the switching loop including, by non-limiting example, shunt resistance, printed circuit board leakage inductances, decoupling capacitor series resistance, one or more parasitics in a switching loop, and any combination thereof; any combination thereof, or any other operating or system parameter of an electrical circuit. The measurements during simulation using the test set up 40 are then used in a product system model file generating system like those disclosed herein to generate a product system model file for use in a system level simulator like those disclosed herein. Particular implementations of the product system model file may include various model parameters such as, by non-limiting example, bus voltage, current in the resonant inductor before a switching event, rate of change of current (di/dt) in the resonant inductor before a switching event, resonant inductor value, or other parameters that enable to product system model file to permits soft switching mode modeling by the system level simulator.

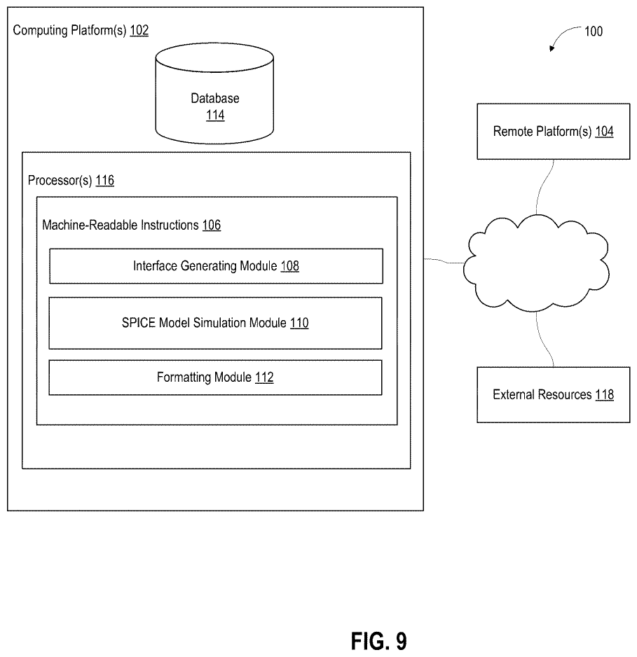

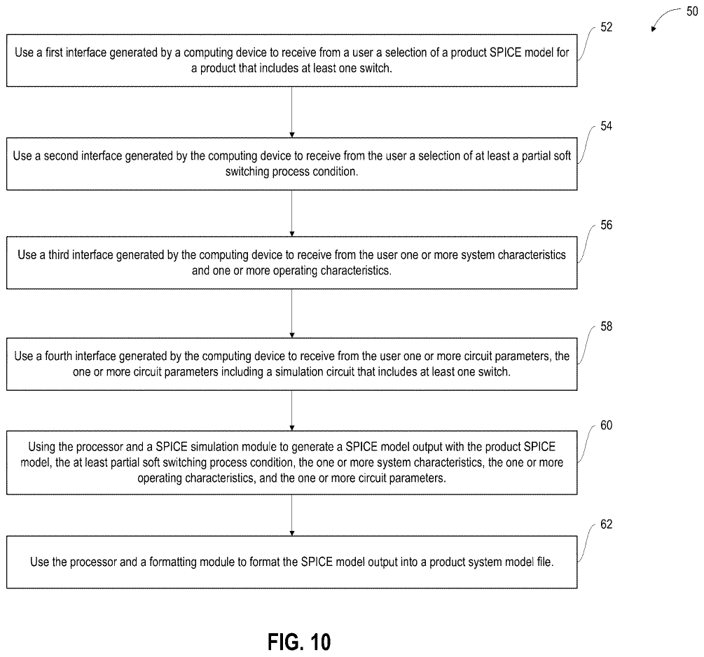

Referring to FIG. 9, a block diagram of an implementation of a system 100 for generating a product system model file for use in system level simulations is illustrated. In some implementations, system 100 may include one or more computing platforms 102. Computing platform(s) 102 may be configured to communicate with one or more remote platforms 104 according to a client/server architecture, a peer-to-peer architecture, and/or other architectures. Remote platform(s) 104 may be configured to communicate with other remote platforms via computing platform(s) 102 and/or according to a client/server architecture, a peer-to-peer architecture, and/or other architectures. Users may access system 100 via remote platform(s) 104. Examples of remote platforms 104 that may be used by users include, by nonliving example, desktop computers, server computers, laptop computers, smart phones, tablets, or any other portable electronic device.

Computing platform(s) 102 may be configured by machine-readable instructions 106. Machine-readable instructions 106 may include one or more instruction modules. The instruction modules may include computer program modules. The instruction modules may include one or more of an interface generating module 108, a SPICE model simulation module 110, and a formatting module 112. Interface generating module 108 works to generate the various computing interfaces illustrated in FIGS. 1-4 of the '382 Application. SPICE model simulation module 110 carries out a series of simulations using a product SPICE model selected by the user that is stored in database 114 which contains a set of product SPICE models like those disclosed in the '382 Application and the '532 and '533 Patents. The results of those simulations, which include the processing of soft switching operating conditions like those disclosed herein, are then processed by formatting module 112 to form a product system model file. In various implementations, the product system model file may be stored in the database 114 for retrieval by the user or others who wish to access the file.

In some implementations, computing platform(s) 102, remote platform(s) 104, and/or external resources 118 may be operatively linked via one or more electronic communication links. For example, such electronic communication links may be established, at least in part, via a network such as the Internet and/or other networks. It will be appreciated that this is not intended to be limiting, and that the scope of this disclosure includes implementations in which computing platform(s) 102, remote platform(s) 104, and/or external resources 130 may be operatively linked via some other communication media.

A given remote platform 104 may include one or more processors configured to execute computer program modules. The computer program modules may be configured to enable an expert or user associated with the given remote platform 104 to interface with system 100 and/or external resources 118, and/or provide other functionality attributed herein to remote platform(s) 104. By way of non-limiting example, a given remote platform 104 and/or a given computing platform 102 may include one or more of a server, a desktop computer, a laptop computer, a handheld computer, a tablet computing platform, a NetBook, a Smartphone, a gaming console, and/or other computing platforms.

External resources 118 may include sources of information outside of system 100, external entities participating with system 100, and/or other resources. In some implementations, some or all of the functionality attributed herein to external resources 130 may be provided by resources included in system 100. As illustrated in FIG. 9, computing platform(s) 102 may include electronic storage/database 114, one or more processors 116, and/or other components. Computing platform(s) 102 may include communication lines, or ports to enable the exchange of information with a network and/or other computing platforms. Illustration of computing platform(s) 102 in FIG. 18 is not intended to be limiting. Computing platform(s) 102 may include a plurality of hardware, software, and/or firmware components operating together to provide the functionality attributed herein to computing platform(s) 102. For example, computing platform(s) 102 may be implemented by a cloud of computing platforms operating together as computing platform(s) 102.

Processor(s) 116 may be configured to provide information processing capabilities in computing platform(s) 102. As such, processor(s) 116 may include one or more of a digital processor, an analog processor, a digital circuit designed to process information, an analog circuit designed to process information, a state machine, and/or other mechanisms for electronically processing information. Although processor(s) 116 is shown in FIG. 9 as a single entity, this is for illustrative purposes only. In some implementations, processor(s) 116 may include a plurality of processing units. These processing units may be physically located within the same device, or processor(s) 116 may represent processing functionality of a plurality of devices operating in coordination. Processor(s) 116 may be configured to execute modules 108, 110, and/or 112, and/or other modules. Processor(s) 116 may be configured to execute modules 108, 110, and/or 112 and/or other modules by software; hardware; firmware; some combination of software, hardware, and/or firmware; and/or other mechanisms for configuring processing capabilities on processor(s) 116. As used herein, the term “module” may refer to any component or set of components that perform the functionality attributed to the module.

This may include one or more physical processors during execution of processor readable instructions, the processor readable instructions, circuitry, hardware, storage media, or any other components.

It should be appreciated that although modules 108, 110, and/or 112 are illustrated in FIG. 9 as being implemented within a single processing unit, in implementations in which processor(s) 116 includes multiple processing units, one or more of modules 108, 110, and/or 112 may be implemented remotely from the other modules. The description of the functionality provided by the different modules 108, 110, and/or 112 described below is for illustrative purposes, and is not intended to be limiting, as any of modules 108, 110, and/or 112 may provide more or less functionality than is described. For example, one or more of modules 108, 110, and/or 112 may be eliminated, and some or all of its functionality may be provided by other ones of modules 108, 110, and/or 112. As another example, processor(s) 116 may be configured to execute one or more additional modules that may perform some or all of the functionality attributed below to one of modules 108, 110, and/or 112.

Referring to FIG. 10, a flow chart of an implementation of a method of generating a product system file 50 is illustrated. The various method implementations may be executed using any of the system implementations disclosed herein. As illustrated, the method includes using a first interface generated by computing device to receive from a user a selection of a product SPICE model for a product that includes at least one switch (semiconductor switch, step 52). In various implementations, the product may be any disclosed in this document or the '382 Application. The first interface may be an interface with a design like that illustrated in FIG. 1 of the '382 Application in various implementations. The method further include using a second interface generated by the computing device to receive from the user a selection at least a partial soft switching processing condition/mode which may be any disclosed herein (step 54). In the '382 Application, the selection of various process conditions is illustrated, and in various method implementations, any of the process conditions disclosed herein may also be selected. In some method implementations, the process conditions may actually themselves include the at least partial soft switching processing condition/mode within the scope of the process parameters being varied/tested for the particular selected process condition. In other implementations, the selection of soft switching may be made explicit. The second interface may have a design like that illustrated in FIG. 2 of the '382 Application.

The method also includes using a third interface generated by the computing device to receive from the user one or more system characteristics and one or more operating characteristics (step 56). The third interface may have a design like that illustrated in FIG. 3 of the '382 Application in various implementations. In various system and method implementations, the one or more system characteristics and one or more operating characteristics may be any disclosed in the '382 application. In various implementations, the one or more system characteristics and one or more operating characteristics include any of the system and operating characteristics identified herein that affect soft switching (delay, bus voltage, etc.). The method also includes using a fourth interface generated by the computing device to receive from the user one or more circuit parameters where the one or more circuit parameters include a simulation circuit that includes at least one switch (step 58). The simulation circuit may be a circuit like that illustrated in FIG. 8 in some implementations. The various simulation circuit implementations contain a schematic design of the internal electrical connections of a semiconductor package including the switching components for use in identifying the specific circuit parameters of the components of the circuit to be varied/tested to the user. The fourth interface may be like the interface design illustrated in FIG. 4 of the '382 Application in various implementations. The specific circuit parameters for a circuit that includes at least one switch include any of those identified component values (inductance, capacitance, etc.) that affect soft switching disclosed herein.

The method also includes using a SPICE simulation module to generate a SPICE model output with the product SPICE model, the at least partial soft switching process condition, the one or more system characteristics, the one or more operating characteristics, and the one or more circuit parameters (step 60). The method also includes using a formatting module to format the SPICE model output into a product system model file which may formatting in any format disclosed in this document or the '382 Application (step 62). Here the method takes the information and utilizes the product SPICE model (which may be any disclosed herein or in the '382 Application) to model the at least partial soft switching operation of the circuit being simulated and then generate a corresponding the product system model file. The resulting product system model file can then be used with a system level simulator to generate a system simulation that fully comprehends the effect of the soft switching on performance characteristics like energy consumption, switching timing, or any other desired system characteristics. Because the soft switching behavior is now comprehended, the system simulation may be more accurate than if double pulse and/or hard switching only analysis was employed with the same circuit design.

In various method and system implementations, the simulation circuit may include a resonant inductor coupled with the at least one switch which may be an inductor type disclosed herein. The method may also include a shunt resistor coupled with the at least one switch. In various method implementations, the one or more circuit characteristics may further include, by non-limiting example, gate resistance, gate loop resistance, source inductance, loop inductance, diode voltage, any combination thereof, or any other circuit or device parameter. The method may also include where the one or more circuit characteristics include, by non-limiting example, shunt resistance, printed circuit board leakage inductances, decoupling capacitor series resistance, one or more parasitics in a switching loop, any combination thereof, or any other circuit or device parameter that affects soft switching behavior of the product. The method may also include where the one or more system characteristics include an output capacitance of an output capacitor of the at least one switch. In various method implementations, the one or more operating characteristics may include an inductance value of the resonant inductor. In various method implementations, the one or more operating characteristics may include a maximum transition time of switching of the at least one switch (or a delay between switching of two or more switches). The method may also include, when generating the SPICE model output, using a current in the resonant inductor before a switching event of the at least one switch and/or using a rate of change of current in the resonant inductor before the switching event of the at least one switch.

In places where the description above refers to particular implementations of product system model file generating systems and implementing components, sub-components, methods and sub-methods, it should be readily apparent that a number of modifications may be made without departing from the spirit thereof and that these implementations, implementing components, sub-components, methods and sub-methods may be applied to other product system model file generating systems and related methods.

What is claimed is:

1. A method of generating a product system model file, the method comprising:
using a processor and a first interface generated by a computing device, selecting a product SPICE model for a product comprising at least one switch;
using a processor and a second interface generated by the computing device, selecting at least a partial soft switching process condition;
using a third interface generated by the computing device, receiving from the user one or more system characteristics and one or more operating characteristics;
using a fourth interface generated by the computing device, receiving from the user one or more circuit parameters, the one or more circuit parameters comprising a simulation circuit comprising at least one switch;
using the processor and a SPICE model simulation module, generating a SPICE model output with the product SPICE model, the at least partial soft switching process condition, the one or more system characteristics, the one or more operating characteristics, and the one or more circuit parameters; and
using the processor and a formatting module, formatting the SPICE model output into a product system model file.

2. The method of claim 1, wherein the product system model file is configured to be used to perform a system level simulation of a system comprising the product.

3. The method of claim 1, wherein the simulation circuit further comprises a resonant inductor coupled with the at least one switch.

4. The method of claim 1, wherein the simulation circuit further comprises a shunt resistor coupled with the at least one switch.

5. The method of claim 1, wherein the one or more circuit parameters further comprise one of shunt resistance, printed circuit board leakage inductances, decoupling capacitor series resistance, one or more parasitics in a switching loop, and any combination thereof.

6. The method of claim 1, wherein the one or more system characteristics comprise an output capacitance of an output capacitor of the at least one switch.

7. The method of claim 1, wherein the one or more operating characteristics comprise bus voltage.

8. The method of claim 3, wherein the one or more system characteristics comprise an inductance value of the resonant inductor.

9. The method of claim 1, wherein the one or more operating characteristics comprises a maximum transition time of switching of the at least one switch.

10. The method of claim 3, wherein generating the SPICE model output further comprises using a current in the resonant inductor before a switching event of the at least one switch and using a rate of change of current in the resonant inductor before the switching event of the at least one switch.

11. A method of generating a product system model file, the method comprising:
using one or more processors and one or more interfaces generated by a computing device associated with a user:
selecting a product SPICE model for a product comprising at least one switch;
selecting a partial soft switching process condition;
receiving one or more system characteristics and one or more operating characteristics;
receiving one or more circuit parameters, the one or more circuit parameters comprising a simulation circuit comprising at least one switch;
using a SPICE model simulation module, generating a SPICE model output with the product SPICE model, the partial soft switching process condition, the one or more system characteristics, the one or more operating characteristics, and the one or more circuit parameters; and
using a formatting module, formatting the SPICE model output into a product system model file.

12. A product system model file generating system comprising:
one or more hardware processors configured by machine-readable instructions to:
use a first interface generated by a computing device to receive from a user a selection of a product SPICE model for a product comprising at least one switch;
use a second interface generated by the computing device to receive from a user a selection of at least a partial soft switching process condition;
use a third interface generated by the computing device to receive from a user a selection of one or more system characteristics and one or more operating characteristics;
use a fourth interface generated by the computing device to receive from the user a selection of one or more circuit parameters, the one or more circuit parameters comprising a simulation circuit comprising at least two switches;
use a SPICE model simulation module to generate a SPICE model output with the product SPICE model, the at least partial soft switching process condition, the one or more system characteristics, the one or more operating characteristics, and the one or more circuit parameters; and
use a formatting module to format the SPICE model output into a product system model file.

13. The system of claim 12, wherein the product system model file is configured to be used to perform a system level simulation of a system comprising the product.

14. The system of claim 12, wherein the simulation circuit further comprises a resonant inductor coupled with the at least one switch.

15. The system of claim 12, wherein the simulation circuit further comprises a shunt resistor coupled with the at least one switch.

16. The system of claim 12, wherein the one or more circuit parameters further comprise one of shunt resistance, printed circuit board leakage inductances, decoupling capacitor series resistance, one or more parasitics in a switching loop, and any combination thereof.

17. The system of claim 12, wherein the one or more system characteristics comprise an output capacitance of an output capacitor of the at least one switch.

18. The system of claim 14, wherein the one or more system characteristics comprise an inductance value of the resonant inductor.

19. The system of claim 12, wherein the one or more operating characteristics comprises a maximum transition time of switching of the at least one switch and a bus voltage.

20. The system of claim 14, wherein using the SPICE model simulation module to generate a SPICE model output with the product SPICE model further comprises using a current in the resonant inductor before a switching event of the at least one switch and using a rate of change of current in the resonant inductor before the switching event of the at least one switch.
